(19) United States
(12) Patent Application Publication
(10) Pub. No.: US 2025/0259903 A1
(43) Pub. Date: Aug. 14, 2025

(54) SEMICONDUCTOR ENCAPSULATION COMPOSITION AND SEMICONDUCTOR PACKAGE INCLUDING THE SAME

(71) Applicant: Samsung Electronics Co., Ltd., Suwon-si (KR)

(72) Inventors: Joonhyeok Jang, Suwon-si (KR); Jaein Won, Suwon-si (KR)

(21) Appl. No.: 18/914,815

(22) Filed: Oct. 14, 2024

(30) Foreign Application Priority Data
Feb. 13, 2024 (KR) 10-2024-0020662

(51) Int. Cl. H01L 23/29; C08K 3/04; C08K 3/22; C08K 3/36; H01L 23/498

(52) U.S. Cl. CPC H01L 23/295; C08K 3/04; C08K 3/22; C08K 3/36; C08K 2003/2227; C08K 2201/001; C08K 2201/005; H01L 23/49811

(57) ABSTRACT

A semiconductor encapsulation composition includes a polymer resin, a hardener, a filler, and an additive configured to adjust a reaction rate between the polymer resin and the hardener, wherein the polymer resin includes a high heat-dissipating resin having a mesogen unit, and the filler includes diamond powder or a mixture of the diamond powder and an inorganic filler.

### CROSS-REFERENCE TO RELATED APPLICATION

This application is based on and claims priority under 35 U.S.C. § 119 to Korean Patent Application No. 10-2024-0020662, filed on Feb. 13, 2024, in the Korean Intellectual Property Office, the disclosure of which is incorporated by reference herein in its entirety.

### BACKGROUND

The inventive concept relates to a semiconductor encapsulation composition.

The inventive concept also relates to a semiconductor package including a semiconductor encapsulation composition.

The present disclosure generally relates to semiconductors, and more particularly, to semiconductor packages including encapsulating structures.

Along with the miniaturization and high functionalization of electronic devices, there is a demand for high densification of semiconductor packages. Accordingly, the demand for highly integrated and miniaturized semiconductor packages has increased. An epoxy molding compound (EMC), a die attach paste (DAP), a die attach film (DAF), and/or an underfill composition may be used as a filling composition of a semiconductor package.

In a semiconductor package manufacturing process that involves a filling process, the filling composition can have thixotropy. In addition, the importance of preventing warpage of a semiconductor package in a semiconductor package manufacturing process has increased. Accordingly, concern about adjustment of the thermal conductivity and the heat diffusion rate of a filling composition has increased.

### SUMMARY

The inventive concept provides a semiconductor encapsulation composition with improved reliability.

The inventive concept also provides a semiconductor package including a semiconductor encapsulation composition with improved reliability.

Aspects of the present disclosure provide a semiconductor device with encapsulating composition.

However, it will be appreciated that aspects of the present invention are not restricted to the detailed examples set forth herein. The above and other aspects of the present invention will become apparent to one of ordinary skill in the art by referencing the detailed exemplary description herein.

According to an aspect of the present disclosure, a semiconductor encapsulation composition can include a polymer resin including a mesogen unit; a hardener; and a filler including diamond powder. The mesogen unit can include a compound configured to increase a thermal conductivity of the resin.

According to some examples of the present disclosure, a semiconductor encapsulating composition includes a polymer resin; a hardener; a filler including diamond powder or a mixture of the diamond powder and an inorganic filler; and an additive configured to adjust a reaction rate between the polymer resin and the hardener. A composition ratio of the filler is 60 wt. % to 95 wt. % with reference to a total weight of the semiconductor encapsulation composition, a composition ratio of the polymer resin is 3 wt. % to 20 wt. % with reference to the total weight of the semiconductor encapsulation composition, and a thermal conductivity of the semiconductor encapsulation composition is at least 5 W/mK.

According to some examples of the present disclosure, a semiconductor package includes a lower redistribution structure; a semiconductor chip on an upper surface of the lower redistribution structure; a plurality of conductive posts on the upper surface of the lower redistribution structure and spaced apart from the semiconductor chip in a direction parallel to the upper surface of the lower redistribution structure; and a molding layer covering the upper surface of the lower redistribution structure and surrounding the semiconductor chip and the plurality of conductive posts, and including a semiconductor encapsulation composition. The semiconductor encapsulation composition includes a polymer resin; a hardener configured to form a matrix by reacting with the polymer resin; and a filler comprising diamond powder or a mixture of the diamond powder and an inorganic filler. A thermal conductivity of the semiconductor encapsulation composition is at least 5 W/mK.

It should be noted that the effects of the present invention are not limited to those described above, and other effects of the present disclosure will be apparent from the following description.

The terminology used herein is for the purpose of describing particular embodiments only and is not intended to be limiting of the invention.

### BRIEF DESCRIPTION OF THE DRAWINGS

Embodiments of the inventive concept will be more clearly understood from the following detailed description taken in conjunction with the accompanying drawings in which:

FIG. 1 illustrates a high heat-dissipation resin according to an embodiments;

FIG. 2 illustrates various types of a mesogen unit included in a high heat-dissipating resin according to an embodiment;

FIG. 3 is a graph illustrating the correlation between the volume of a filler and thermal conductivity for each semiconductor encapsulation composition type;

FIG. 4 is a graph illustrating the correlation among the composition ratio of a filler, thermal conductivity, and a heat diffusion rate;

FIG. 5 is a graph illustrating the correlation between the composition ratio of a filler and thermal conductivity for each polymer resin type; and

FIG. 6 is a cross-sectional view of a semiconductor package according to an embodiment.

### DETAILED DESCRIPTION OF THE EMBODIMENTS

The inventive concept may allow various kinds of change or modification and various changes in form, and specific embodiments will be illustrated in drawings and described in detail in the specification. However, the specific embodiments are not intended to limit the inventive concept to a specific disclosing form. The embodiments described below are only illustrative, and various changes in form and details may be made therein.

The use of all illustrations or illustrative terms is simply to describe the technical idea in detail, and the scope is not limited due to the illustrations or illustrative terms unless they are limited by claims.

Hereinafter, unless there is a particular description, in the specification, the vertical direction may be defined as the Z direction, and each of a first direction and a second direction may be defined as a direction that is perpendicular to the Z direction. The first direction may be referred to as X, and the second direction may be referred to as Y. A vertical level may be referred to as a height level in the vertical direction Z. A horizontal width may be referred to as a length in a horizontal direction X and/or Y, and a vertical length may be referred to as a length in the vertical direction Z.

It will be understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

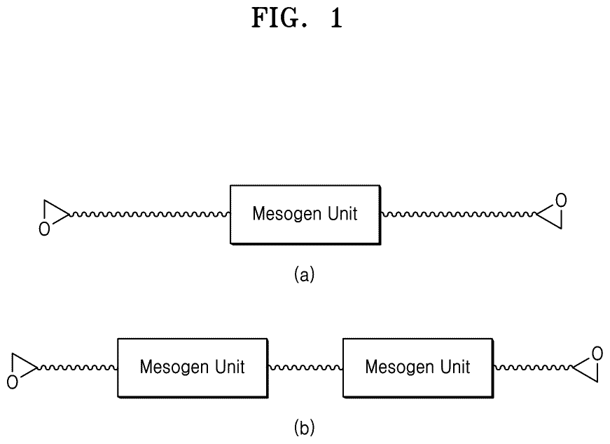

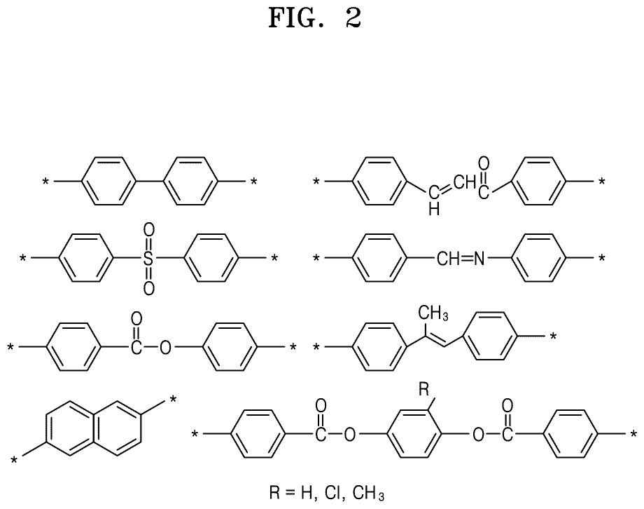

FIG. 1 illustrates a high heat-dissipating resin according to an embodiment. FIG. 2 illustrates types of a mesogen unit included in a high heat-dissipating resin according to an embodiment. Referring to FIGS. 1 and 2, a semiconductor encapsulation composition may be an epoxy molding compound (EMC). For example, the semiconductor encapsulation composition may be a semiconductor package filling composition. In some embodiments, the semiconductor encapsulation composition can include a polymer resin, a hardener, and a filler. In some embodiments, the semiconductor encapsulation composition can further include one or more additives.

In packaged semiconductor devices, an EMC is typically used to encapsulate the delicate semiconductor die and associated circuitry within a protective casing. This encapsulation can shield the components from physical damage, moisture, dust, and other environmental factors. EMC can include thermally conductive fillers to help dissipate heat generated by the semiconductor device during operation. Effective thermal management is helpful to maintain the performance and longevity of the device. EMC can provide electrical insulation, prevent short circuits and ensure reliable operation of the semiconductor device. Such an insulation can help maintaining the integrity of the electronic signals within the device. Additionally, EMC can offer resistance to various chemicals, including solvents, acids, and bases, ensuring that the semiconductor device remains unaffected by chemical exposure during manufacturing and throughout its operational life. In some embodiments, the semiconductor encapsulation composition can be transparent.

Epoxy resin is a versatile polymer with adhesive properties, chemical resistance, and mechanical strength. It can consist of a resin and a hardener, which reacts to form a rigid, durable material. The rigid nature of epoxy offers mechanical support to the fragile semiconductor die, protecting it from mechanical stresses and vibrations that could cause damage or failure. Epoxy resin can exhibit adhesion to a variety of materials used in semiconductor packaging, such as metals, ceramics, and other polymers. This adhesion ensures a secure bond between the encapsulant and the components, preventing delamination and maintaining the structural integrity of the package. Resins may be synthesized using monomers having molecular weights of about 50 g/mol to about 1000 g/mol.

The semiconductor encapsulation composition may include or be a polymer resin. The polymer resin may include or be a single polymer resin, or a mixture of two or more polymer resins. In some embodiments, the epoxy resin, e.g., the polymer resin, can include a first resin and a second resin. In such embodiments, the first resin and the second resin can be made of different materials. As a non-limiting example, while the first resin can be a regular resin (normal resin), the second resin may be a high heat-dissipating resin. In an embodiment, the polymer resin includes only the high heat-dissipating resin, i.e., the second resin.

A high heat-dissipating resin can be a polymer material designed to effectively transfer and dissipate heat away from electronic components or other heat-generating elements on the semiconductor devices. The high heat-dissipating resin can be a thermally conductive material. In some embodiments, the high heat-dissipating resin can include a mesogen unit. The mesogen unit can include a mesogen compound. Generally, a mesogen compound is a molecule that exhibits properties allowing it to form liquid crystalline phases. Such a compound can be characterized by its ability to organize itself into an ordered structure while still retaining fluidity. Mesogen compounds typically have a rigid, rod-like, or disc-like core structure. This core can be accompanied by flexible terminal chains that influence the temperature range and specific type of liquid crystalline phase formed.

The first resin may be a normal resin. The semiconductor encapsulation composition may include a hardener configured to form a matrix by reacting with the first resin.

The first resin as a normal resin may include or be a thermosetting polymer. Thermosetting polymers may be bonded to each other through a hardening process to form a polymer matrix. The hardener may be, for example, a thermosetting agent. The hardener may be dispersed in a filler to be described below.

The high heat-dissipating resin, e.g., the second resin, when described as having a mesogen unit or including a mesogen unit, may have one mesogen unit (e.g., may be a polymer chain having one mesogen unit), as shown in FIG. 1(a), or may have two mesogen units (e.g., may be a polymer chain having two mesogen units), as shown in FIG. 1(b). The high heat-dissipating resin having a mesogen unit may have high molecular orientation and crystallinity. In some embodiments, the molecular orientation of the high heat-dissipating resin, e.g., second resin with one mesogen unit, as shown for example in FIG. 1(a), is different from the molecular orientation of the high heat-dissipating resin with two mesogen units, as shown in FIG. 1(b). Therefore, the high heat-dissipating resin can include one mesogen unit or two mesogen units with different structures and connected together as shown in FIGS. 1A-1B. A composition ratio of the high heat-dissipating resin including a mesogen unit can be 10 wt. % to 100 wt. % with reference to a weight of the polymer resin.

In some embodiments, the polymer may be a thermosetting polymer. Thermosetting polymers can be bonded to each other through a hardening process to form a polymer matrix. The hardener can be, for example, a thermosetting agent. In some embodiments, the hardener can be dispersed in a filler which is described below. In some embodiments, the thermosetting polymer may include one or more types selected from a group consisting of, for example, epoxy-based polymers and bismaleimide-based polymers. In some embodiments, the first resin can include an epoxy resin such as biphenyl, and/or bisphenol A, and/or bisphenol F.

The epoxy-based polymers may include, for example, a bisphenol A-type epoxy resin, a bisphenol F-type epoxy resin, a naphthalene-type epoxy resin, an aminophenol-type epoxy resin, a hydrogenated bisphenol-type epoxy resin, an alicyclic epoxy resin, an alcohol ether-type epoxy resin, a cyclic aliphatic-type epoxy resin, a fluorene-type epoxy resin, a siloxane-based epoxy resin, and the like but are not limited thereto. The epoxy-based polymers may be used alone or as a mixture of two or more types thereof.

The bismaleimide-based polymers are polymers obtained by polymerizing maleimide monomers including one or more maleimide groups. The maleimide monomers may include, for example, N-phenyl maleimide, N-(2-methylphenyl)maleimide, N-(4-methylphenyl)maleimide, N-(2,6-dimethylphenyl)maleimide, bis(4-maleimidophenyl)methane, 2,2-bis(4-(4-maleimidophenoxy)-phenyl)propane, bis(3,5-dimethyl-4-maleimidophenyl)methane, bis(3-ethyl-5-dimethyl-4-maleimidophenyl)methane, bis(3,5-diethyl-4-maleimidophenyl)methane, polyphenylmethanebismaleimide, other maleimides containing a biphenyl structure, and the like, but the inventive concept is not limited thereto.

Alternatively, the bismaleimide-based polymers may be obtained from a prepolymer including a maleimide group, and the prepolymer may be an arbitrary type or a mixture of at least two types of, for example, an N-phenyl maleimide prepolymer, an N-(2-methylphenyl)maleimide prepolymer, an N-(4-methylphenyl)maleimide prepolymer, an N-(2,6-dimethylphenyl)maleimide prepolymer, a bis(4-maleimidophenyl)methane prepolymer, a 2,2-bis(4-(4-maleimidophenoxy)-phenyl)propane prepolymer, a bis(3,5-dimethyl-4-maleimidophenyl)methane prepolymer, a bis(3-ethyl-5-methyl-4-maleimidophenyl)methane prepolymer, a bis(3,5-diethyl-4-maleimidophenyl)methane prepolymer, a polyphenylmethanebismaleimide prepolymer, a maleimide prepolymer containing a biphenyl structure, a prepolymer of N-phenyl maleimide and an amine-based compound, a prepolymer of N-(2-methylphenyl)maleimide and an amine-based compound, a prepolymer of N-(4-methylphenyl)maleimide and an amine-based compound, a prepolymer of N-(2,6-dimethylphenyl)maleimide and an amine-based compound, a prepolymer of bis(4-maleimidophenyl)methane and an amine-based compound, a prepolymer of 2,2-bis(4-(4-maleimidophenoxy)-phenyl)propane and an amine-based compound, a prepolymer of bis(3,5-dimethyl-4-maleimidophenyl)methane and an amine-based compound, a prepolymer of bis(3-ethyl-5-methyl-4-maleimidophenyl)methane and an amine-based compound, a prepolymer of bis(3,5-diethyl-4-maleimidophenyl)methane and an amine-based compound, a prepolymer of maleimide containing a biphenyl structure and an amine-based compound, and a prepolymer of polyphenylmethanebismaleimide and an amine-based compound, but the inventive concept is not limited thereto.

In embodiments, the composition ratio of the polymer resin including at least one of a resin having the thermosetting polymer and the high heat-dissipating resin may be about 3 wt. % to about 20 wt. % with reference to the total weight of the semiconductor encapsulation composition. For example, the composition ratio of the polymer resin may be 5 wt. % to about 20 wt. %, about 3 wt. % to about 10 wt. %, or about 10 wt. % to about 15 wt. % with reference to the total weight of the semiconductor encapsulation composition.

Referring to FIGS. 1, 2, and 6, a molding layer, ML 230, may contain a binder polymer. The binder polymer may be illustrated as strands of lines.

In embodiments, the binder polymer may include a thermoplastic polymer. The thermoplastic polymer may include one or more types selected from a group consisting of, for example, acrylic polymers and phenoxy-based polymers.

The acrylic polymers are obtained by radical polymerization using an acrylic monomer as a raw material. In some embodiments, the acrylic monomer may include, for example, methyl(met)acrylate, ethyl(met)acrylate, propyl(met)acrylate, isopropyl(met)acrylate, butyl(met)acrylate, isobutyl(met)acrylate, hexyl(met)acrylate, 2-ethylhexyl(met)acrylate, n-octyl(met)acrylate, isooctyl(met)acrylate, n-nonyl(met)acrylate, isononyl(met)acrylate, n-decyl(met)acrylate, isodecyl(met)acrylate, n-dodecyl(met)acrylate, n-tridecyl(met)acrylate, n-tetradecyl(met)acrylate, 2-hydroxyethyl(met)acrylate, 2-hydroxypropyl(met)acrylate, 4-hydroxybutyl(met)acrylate, 6-hydroxyhexyl(met)acrylate, 8-hydroxyoctyl(met)acrylate, 10-hydroxydecyl(met)acrylate, 12-hydroxylauryl(met)acrylate, (4-hydroxymethylcyclohexyl)methylacrylate, N-methylol(met)acrylate, ethyleneglycoldi(met)acrylate, diethyleneglycoldi(met)acrylate, tetraethyleneglycoldi(met)acrylate, neopentylglycoldi(met)acrylate, 1,6-hexanedioldi(met)acrylate, trimethylolpropanetri(met)acrylate, pentaerythritoltri(met)acrylate, dipentaerythritolhexa(met)acrylate, divinylbenzene, N,N′-methylenebisacrylamide, or the like, but the inventive concept is not limited thereto.

The phenoxy-based polymers may be obtained by polymerizing a monomer, such as phenoxyethylacrylate, phenoxydiethyleneglycol acrylate, phenoxypolyethyleneglycol acrylate, nonyl phenoxypolyethyleneglycol acrylate, nonyl phenoxypolypropylene glycol acrylate, nonyl phenoxyethylene glycol acrylate, or 2-hydroxy-3-phenoxypropyl(met)acrylate. In some embodiment, the phenoxy-based polymers may include poly(2,6-dilauryl-1,4-phenylene)ether, poly(2,6-diphenyl-1,4-phenylene)ether, poly(2-methyl-6-phenyl-1,4-phenylene)ether, poly(2,6-dibenzyl-1,4-phenylene)ether, poly(2,6-dimethyl-1,4-phenylene)ether, poly(2,6-diethyl-1,4-phenylene)ether, poly(2-methyl-6-ethyl-1,4-phenylene)ether, poly(2,6-dipropyl-1,4-phenylene)ether, poly(2-ethyl-6-propyl-1,4-phenylene)ether, poly(2-methyl-1,4-phenylene)ether, poly(3-methyl-1,4-phenylene)ether, poly(2-methyl-6-allyl-1,4-phenylene)ether, poly(2,3,6-trimethyl-1,4-phenylene)ether, poly(2,3,5,6-tetramethyl-1,4-phenylene)ether, poly(2,5-dimethyl-1,4-phenylene)ether, and the like, but the inventive concept is not limited thereto.

The mesogen unit included in the high heat-dissipating resin may include one of the plurality of polymer compounds shown in FIG. 2. A substituent R in a polymer compound shown in FIG. 2 may be one of hydrogen (H), chlorine (Cl), and a methyl group (CH₃).

The composition ratio of the high heat-dissipating resin may be about 10 wt. % to about 100 wt. % with reference to the weight of the polymer resin. For example, the composition ratio of the high heat-dissipating resin may be about 10 wt. %, about 20 wt. %, about 50 wt. %, or about 100 wt. % with reference to the weight of the polymer resin. When the composition ratio of the high heat-dissipating resin is 100 wt. % with reference to the weight of the polymer resin, the polymer resin may include only the high heat-dissipating resin without a normal resin, e.g., the polymer resin includes only the second resin without the first resin.

The hardener contained in the semiconductor encapsulation composition may include an anhydride group. For example, the hardener may include nadic maleic anhydride, dodecyl succinic anhydride, maleic anhydride, succinic anhydride, methyl tetrahydro phthalic anhydride, hexahydro phthalic anhydride, hexahydro phthalic anhydride, tetrahydro phthalic anhydride, pyromellitic dianhydride, tetrahydro phthalic anhydride, cyclohexanedicarboxylic anhydride, methyl tetrahydro phthalic anhydride, 1,2,4-benzenetricarboxylic anhydride, benzopenone-3,3′, and/or 4,4′-tetracarboxylic dianhydride. As another example, the hardener may be a photocurable agent.

The composition ratio of the hardener included in the semiconductor encapsulation composition may be about 2 wt. % to about 10 wt. % with reference to the total weight of the semiconductor encapsulation composition. In an embodiment, the composition ratio of the hardener included in the semiconductor encapsulation composition may be about 2 wt. % to about 10 wt. %, about 5 wt. % to about 10 wt. %, or about 2 wt. % to about 8 wt. % with reference to the total weight of the semiconductor encapsulation composition. In an embodiment, the hardener may be a thermosetting agent containing an anhydride group.

The semiconductor encapsulation composition may include a filler. Typically, silica and alumina are used as inorganic fillers in EMC for encapsulating packaged semiconductor devices. These materials are favored due to their beneficial properties, such as chemical inertness, thermal stability, and the ability to provide enhanced mechanical strength and electrical insulation. However, the thermal conductivity of silica and alumina is relatively low, which can be a limitation in applications requiring efficient heat dissipation.

To address this issue, in some embodiments, diamond powder is used as an inorganic filler to improve the thermal conductivity of the EMC. Diamond powder can offer a thermal conductivity range of 1000 to 2200 W/mK, significantly enhancing the heat dissipation capabilities of the encapsulating material. By incorporating diamond powder, the thermal management properties of the EMC can be greatly improved, making them more suitable for high-performance electronic applications where effective heat dissipation is particularly important for maintaining functionality and longevity of the devices.

In some embodiments, the filler, which includes the diamond powder, can make up 50% to 95% of the total weight of the total semiconductor encapsulating compound, and in some embodiments 60% to 95%. Such a high proportion of the filler can better ensure that the semiconductor encapsulating composition benefits from the thermal conductivity of the diamond powder, making it highly effective in applications where efficient heat dissipation is crucial.

In some embodiments, the filler may include at least one of one or more inorganic fillers (other than diamond powder) and/or diamond powder. The composition ratio of the diamond powder may be about 10 wt. % to about 100 wt. % with reference to the weight of the filler, and the composition ratio of the one or more inorganic fillers, which may be inorganic compounds, may be about 0 wt. % to about 90 wt. % with reference to the weight of the filler. In an embodiment, the composition ratio of the diamond powder may be about 10 wt. %, about 20 wt. %, about 50 wt. %, or about 100 wt. % with reference to the weight of the filler. In an embodiment, the composition ratio of the one or more inorganic fillers may be about 90 wt. %, about 80 wt. %, about 50 wt. %, or about 0 wt. % with reference to the weight of the filler. In some embodiments, when the composition ratio of the filler is greater than 50 wt. % with reference to the weight of the epoxy molding compound, the composition ratio of the diamond powder may be about 10 wt. % to about 100 wt. % with reference to the weight of the filler. The one or more inorganic fillers may include one or two among silicon dioxide (SiO₂), aluminum oxide (Al₂O₃), aluminum nitride (AlN), boron nitride (BN) magnesium oxide (MgO), and a compound thereof. The thermal conductivity of the diamond powder may be about 1000 W/mK to about 2200 W/mK. In an embodiment, the size of each grain of the diamond powder may be about 20 micrometers to about 30 micrometers.

The values of the thermal conductivities, the coefficients of thermal expansion (CTEs), and the like of the one or more inorganic fillers and the diamond powder are shown in Table 1. The items of Table 1 define each of CTE, elastic modulus, Vickers hardness, specific gravity, and dielectric constant.

TABLE 1

| | | | | | Diamond powder |
|---|---|---|---|---|---|
| Item | SiO₂ | Al₂O₃ | BN | AIN | C-filler |
| Thermal | 1.3 | 30 | 110 | 270 | 2,000 |
| conductivity | | | | | |
| [W/mK] | | | | | |
| CTE | 0.5 | 7.3 | 4.0 | 4.6 | 1.0 |
| [ppm/K] | | | | | |
| Elastic modulus | 73 | 300 | 47 | 330 | 900 |
| [Gpa] | | | | | |
| Vickers hardness | 6 | 20 | 2 | 12 | 10,000 |
| [Hv] | | | | | |
| Specific gravity | 2.2 | 4.0 | 2.3 | 3.3 | 3.5 |
| Dielectric constant | 3.8 | 8.9 | 4.1 | 8.8 | 5.5 |

The filler may further include flux. The flux may function as an antioxidant. The flux may include organic acid, such as formic acid, acetic acid, lactic acid, glutamic acid, oleic acid, rosolic acid, 2,2-bis(hydroxymethylene)propanoic acid, butanoic acid, propanoic acid, tannic acid, gluconic acid, pentanoic acid, hexanoic acid, hydrobromic acid, hydrochloric acid, uric acid, hydrofluoric acid, sulfuric acid, benzglutaric acid, malic acid, phosphoric acid, oxalic acid, uranic acid, hydrochlorate, erchloric acid, gallic acid, phosphorous acid, citric acid, malonic acid, tartartic acid, phthalic acid, glutaric acid, hexanoic acid, propionic acid, stearic acid, ascorbic acid, acetylsalicylic acid, azelaic acid, benzilic acid, and/or fumaric acid.

The semiconductor encapsulation composition may include one or more additives. The one or more additives may be configured to adjust a reaction speed between the polymer resin and the hardener. The composition ratio of the one or more additives may be about 0 wt. % to about 10 wt. % with reference to the total weight of the semiconductor encapsulation composition. In an embodiment, the composition ratio of the one or more additives may be about 10 wt. %, about 5 wt. %, or about 0 wt. % with reference to the total weight of the semiconductor encapsulation composition.

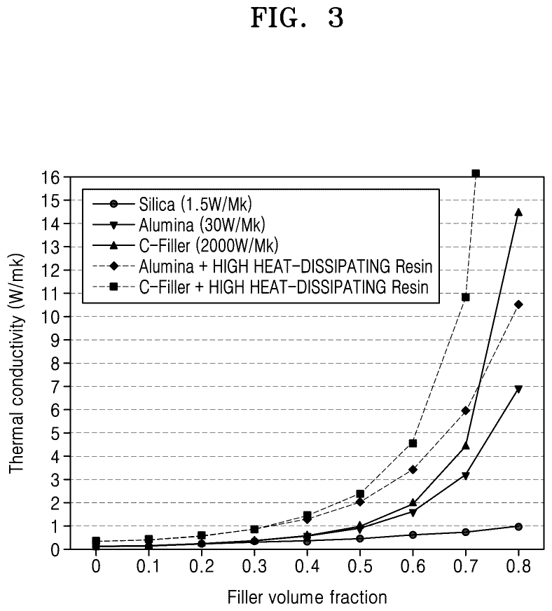

FIG. 3 is a graph illustrating the correlation between the volume of a filler and thermal conductivity for each semiconductor encapsulation composition type. FIG. 3 shows silica, i.e., SiO₂, with a thermal conductivity of about 1.5 W/mK, Alumina, i.e., Al₂O₃, with a thermal conductivity of about 30 W/mK, and C-filler, i.e., the diamond powder, with a thermal conductivity of about 2000 W/mK. Data indicated by the dashed line shows a high heat-dissipating resin-added semiconductor encapsulation composition. The horizontal axis depicts a composition ratio, and the vertical axis depicts a thermal conductivity.

For the silica, even when the composition ratio of a filler is 0.8, the thermal conductivity of a semiconductor encapsulation composition is only less than 1 W/mK. For the alumina, when the composition ratio of a filler is 0.7, the thermal conductivity of a semiconductor encapsulation composition may be about 3 W/mK, and even when the composition ratio of the filler is 0.8, the thermal conductivity of the semiconductor encapsulation composition is only less than 7 W/mK.

For the C-filler, i.e., the diamond powder, when the composition ratio of a filler is 0.7, the thermal conductivity of a semiconductor encapsulation composition may be about 4.5 W/mK, which is greater than that of the silica or the alumina, and when the composition ratio of the filler is 0.8, the thermal conductivity of the semiconductor encapsulation composition is 14 W/mK or greater.

In addition, when the high heat-dissipating resin with a mesogen unit is added to the alumina, a thermal conductivity higher than that of alumina only may be ensured. For example, when the composition ratio of a filler to which the alumina and the high heat-dissipating resin are added is 0.7, the filler may have a thermal conductivity of about 6 W/mK, which is greater by about 3 W/mK than that of the alumina only, and when the composition ratio of the filler is 0.8, the semiconductor encapsulation composition may have a thermal conductivity of about 10.5 W/mK, which is greater by about 3.5 W/mK than that of the alumina only.

In addition, when the high heat-dissipating resin with a mesogen unit is added to the C-filler, a thermal conductivity higher than that of diamond powder only may be ensured. For example, when the composition ratio of a filler in which the high heat-dissipating resin having a mesogen unit according to the inventive concept is added to the C-filler is 0.7. the semiconductor encapsulation composition may have a thermal conductivity of about 11 W/mK, which is greater by about 6.5 W/mK than that of the C-filler only, and when the composition ratio of the filler is 0.8, the semiconductor encapsulation composition may have a thermal conductivity of 16 W/mK or greater.

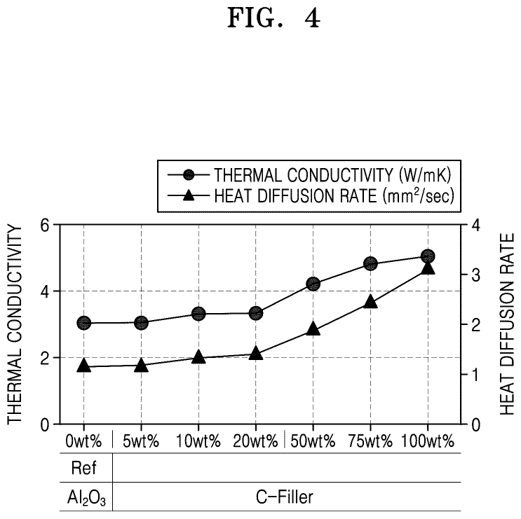

FIG. 4 illustrates the correlation among the composition ratio of a filler, thermal conductivity, and a heat diffusion rate. As shown in FIG. 4, reference (Ref) on the horizontal axis is Al₂O₃, and the composition ratio (wt. %) on the horizontal axis represents 5 wt. % to 100 wt. % indicating the composition ratio of C-filler, i.e., diamond powder. The left vertical axis shows the thermal conductivity, and the right vertical axis shows the heat diffusion rate. The margins of increase in both the thermal conductivity and the heat diffusion rate of the filler increase when the composition ratio of the diamond powder is 50 wt. % or greater, i.e., 50 wt. %, 75 wt. %, and 100 wt. %. Although the differences between the thermal conductivity and the heat diffusion rate of the filler and the thermal conductivity and the heat diffusion rate of Al₂O₃ are only 1 W/mK or less and 1 mm²/sec or less, respectively, when the composition ratio of the diamond powder is 20 wt. % or less, the differences increase to 2 W/mK or greater and 2 mm²/sec or greater, respectively, when the composition ratio of the diamond powder is 50 wt. % or greater.

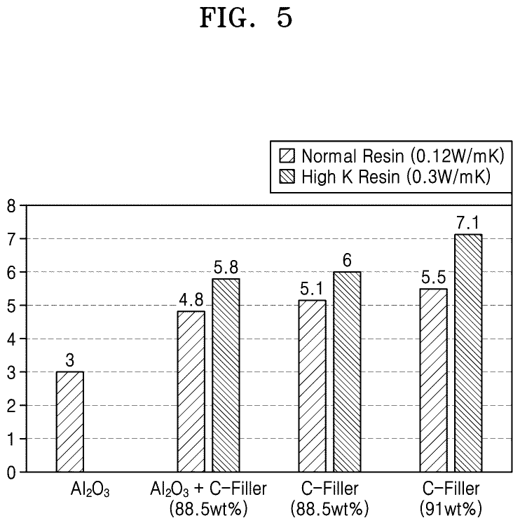

FIG. 5 illustrates the correlation between the composition ratio of a filler and thermal conductivity for each polymer resin type. The horizontal axis shows the composition ratio of each of Al₂O₃ and mixed compositions of Al₂O₃ and the diamond powder, and the vertical axis shows a thermal conductivity. In addition, when two bar graphs are formed on at least one section of the horizontal axis, one of the two bar graphs indicates that regular resin with a thermal conductivity of about 0.12 W/mK is added to the filler, and the other bar graph indicates that the high heat-dissipating resin with a thermal conductivity of about 0.3 W/mK is added to the filler.

The first graph shows a case in which Al₂O₃ only is used as an inorganic filler, i.e., the composition ratio of Al₂O₃ in the inorganic filler is 100 wt. % with reference to the weight of the filler, and the first resin is added to the filler. Referring to the first graph, the thermal conductivity of a semiconductor encapsulation composition is only about 3 W/mK. Referring to the second graph, which shows a filler having Al₂O₃ and diamond powder together having a composition ratio of 85 wt. % with reference to the weight of the semiconductor encapsulation composition, the thermal conductivity of a semiconductor encapsulation composition with a normal resin is about 4.8 W/mK. Referring to the third graph, which shows a filler having Al₂O₃ and diamond powder together having a composition ratio of 85 wt. % with reference to the weight of the semiconductor encapsulation composition, the thermal conductivity of a semiconductor encapsulation composition with a high heat-dissipating resin is about 5.8 W/mK, which is higher by about 1 W/mK than the case in which the normal resin is added. Additionally, when the first graph is compared to the second graph, the filler having Al₂O₃ and diamond powder with a composition ratio of 85 wt. % with reference to the weight of the semiconductor encapsulation composition has an increased thermal conductivity by about 1.8 W/mK compared to the case in which the composition ratio of Al₂O₃ in a filler is 100 wt. %.

Referring to the fourth graph, only the diamond powder is included in the filler and the composition ratio of the diamond powder (i.e., filler) is about 88.5 wt. % with reference to the weight of the semiconductor encapsulation composition. In such a case, the thermal conductivity of a semiconductor encapsulation composition with only regular resin is about 5.1 W/mK. Referring to the fifth graph, which is the same filler composition as the fourth graph, the thermal conductivity of a semiconductor encapsulation composition with a high heat-dissipating resin is about 6 W/mK. When the second graph is compared to the fourth graph, the thermal conductivity of the case in which only the diamond powder is included in the filler has an increased thermal conductivity by about 0.3 W/mK compared to the case in which Al₂O₃ and the diamond powder are included in the filler. Additionally, when the third graph is compared to the fifth graph, the thermal conductivity of the case in which only the diamond powder is included in the filler, has an increased thermal conductivity by about 0.2 W/mK compared to the case in which Al₂O₃ and the diamond powder are included in the filler. When the fourth graph is compared to the fifth graph, the thermal conductivity of the case in which the high heat-dissipating resin is added, has an increased thermal conductivity by about 0.9 W/mK compared to the case in which the normal resin is added.

Referring to the sixth graph, only the diamond powder is added to the filler and the composition ratio of the diamond powder is about 91 wt. % with reference to the weight of the semiconductor encapsulation composition and the regular resin is added. In such a case, the thermal conductivity of a semiconductor encapsulation composition is about 5.5 W/mK. Referring to the seventh graph, only the diamond powder is added to the filler and the composition ratio of the diamond powder is about 91 wt. % with reference to the weight of the semiconductor encapsulation composition, and the high heat-dissipating resin is added. In this case, the thermal conductivity of a semiconductor encapsulation composition is about 7.1 W/mK. When the fourth graph is compared to the sixth graph, if the composition ratio of the diamond powder increases from 88.5 wt. % to 91 wt. % with reference to the weight of the semiconductor encapsulation composition, a thermal conductivity may increase by about 0.4 W/mK, and when the fifth graph is compared to the seventh graph, if the composition ratio of the diamond powder increases from 88.5 wt. % to 91 wt. % with reference to the weight of the semiconductor encapsulation composition, a thermal conductivity increases by about 0.9 W/mK. When the sixth graph is compared to the seventh graph, the thermal conductivity of the case in which the high heat-dissipating resin is added, has an increased thermal conductivity by about 1.6 W/mK compared to the case in which the normal resin is added. Therefore, as the composition ratio of the diamond powder increases, higher thermal conductivity may be obtained. Further, when the high heat-dissipating resin is added, a higher thermal conductivity can be achieved.

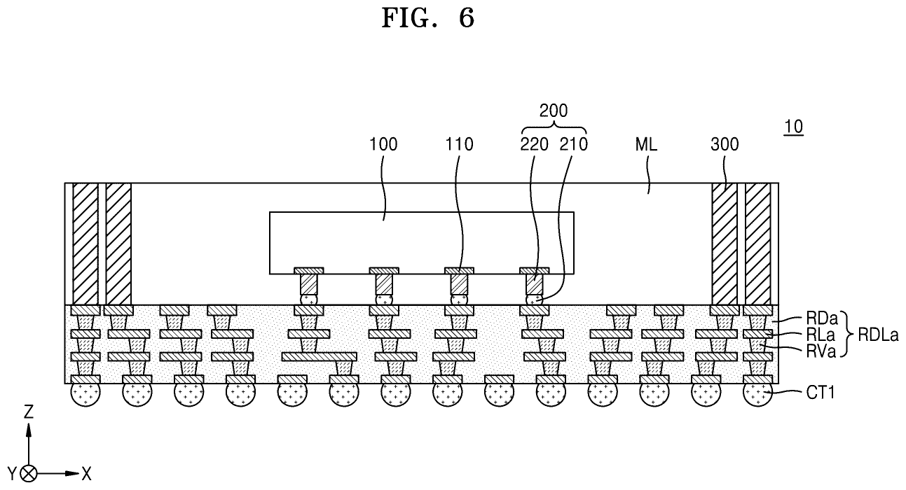

FIG. 6 is a cross-sectional view of a semiconductor package 10 according to an embodiment. Referring to FIGS. 1, 5, and 6, the semiconductor package 10 may include a lower redistribution structure RDLa, a semiconductor chip 100 on the upper surface of the lower redistribution structure RDLa, a plurality of conductive posts 300 on the upper surface of the lower redistribution structure RDLa and spaced apart from the semiconductor chip 100 in a direction parallel to the upper surface of the lower redistribution structure RDLa, and a molding layer ML covering the upper surface of the lower redistribution structure RDLa, surrounding the semiconductor package 10 and the plurality of conductive posts 300, and including a semiconductor encapsulation composition. The semiconductor encapsulation composition included in the molding layer ML of FIG. 6 may correspond to the semiconductor encapsulation composition described with reference to FIGS. 1 to 5.

The semiconductor package 10 may include a plurality of chip connection terminals 200 between the lower redistribution structure RDLa and the semiconductor chip 100, and each of the plurality of chip connection terminals 200 may include a lower filler 210 electrically connected to the lower redistribution structure RDLa and one of the plurality of conductive caps 220 disposed between the lower filler 210 and the semiconductor chip 100 to electrically connect the semiconductor chip 100 to the lower filler 210.

The semiconductor chip 100 may include a plurality of semiconductor chip pads 110 disposed at portions where the semiconductor chip 100 is in contact with a plurality of conductive caps 220.

As shown in FIG. 6, the plurality of conductive posts 300 may be arranged in a plurality of rows. The plurality of conductive posts 300 may be electrically connected to the lower redistribution structure RDLa.

The semiconductor chip 100 of the semiconductor package 10 may include an active surface and an inactive surface that is opposite to the active surface. In some embodiments, the semiconductor chip 100 may be on the upper surface of the lower redistribution structure RDLa such that the active surface of the semiconductor chip 100 faces the lower redistribution structure RDLa, and the semiconductor chip 100 may include the plurality of semiconductor chip pads 110 at a lower end portion thereof facing the lower redistribution structure RDLa in the vertical direction. The plurality of semiconductor chip pads 110 may be electrically connected to individual devices on the active surface of the semiconductor chip 100.

The lower redistribution structure RDLa of the semiconductor package 10 may include a plurality of lower wiring layers RLa, a plurality of lower vertical vias RVa connecting the plurality of lower wiring layers RLa to one another in the vertical direction, and a lower insulating layer RDa surrounding the plurality of lower wiring layers RLa and the plurality of lower vertical vias RVa.

The lower insulating layer RDa may include at least one material selected from among a phenol resin, an epoxy resin, and polyimide. The lower insulating layer RDa may include at least one material selected from among, for example, frame retardant 4 (FR-4), tetrafunctional epoxy, polyphenylene ether, epoxy/polyphenylene oxide, bismaleimide triazine (BT), Thermount, cyanate ester, polyimide, and a liquid crystal polymer.

Each of the plurality of lower vertical vias RVa may include copper (Cu) or an alloy including Cu. For example, each of the plurality of lower vertical vias RVa may have a structure in which Cu or an alloy including Cu is stacked on a seed layer including Cu, titanium (Ti), titanium tungsten (TiW), titanium nitride (TiN), tantalum (Ta), tantalum nitride (TaN), chromium (Cr), Cu/Ti meaning Cu stacked on Ti, or Cu/TiW meaning Cu stacked on TiW, but is not limited thereto. In some embodiments, the plurality of lower vertical vias RVa may be formed to fill a portion of a via through hole penetrating the lower insulating layer RDa while covering the inner wall of the via through hole.

Each of the plurality of lower wiring layers RLa may include electrolytically deposited (ED) copper foil, rolled-annealed (RA) copper foil, stainless steel foil, Al foil, ultra-thin Cu foil, sputtered Cu, a Cu alloy, or the like.

A semiconductor substrate (not shown) including the semiconductor chip 100 may include a semiconductor material, for example, silicon (Si) or germanium (Ge). Alternatively, the semiconductor substrate may include a compound semiconductor material, such as silicon carbide (SiC), gallium arsenide (GaAs), indium arsenide (InAs), or indium phosphide (InP). The semiconductor substrate may include a conductive region, e.g., an impurity-doped well. The semiconductor substrate may have various device isolation structures, such as a shallow trench isolation (STI) structure.

The semiconductor chip 100 may include a conductive region, e.g., an impurity-doped well or an impurity-doped structure. A semiconductor device layer including individual devices may be provided on the active surface of the semiconductor chip 100. The individual devices may include, for example, transistors. The individual devices may include microelectronic devices, e.g., a metal-oxide-semiconductor field effect transistor (MOSFET), a system large scale integration (LSI) chip, an image sensor, such as a complementary metal-oxide-semiconductor (CMOS) imaging sensor (CIS), a micro-electro-mechanical system (MEMS), active devices, passive devices, and the like.

The semiconductor chip 100 may be a memory chip or a logic chip. The memory chip may be a volatile memory semiconductor device, such as dynamic random access memory (DRAM) or static random access memory (SRAM), or a nonvolatile memory semiconductor device, such as phase-change random access memory (PRAM), magnetic random access memory (MRAM), ferroelectric random access memory (FeRAM), or resistive random access memory (RRAM). The logic chip may be a central processing unit (CPU) chip, a graphics processing unit (GPU) chip, an application processor (AP) chip, or an application specific integrated circuit (ASIC) chip.

In some embodiments, each of the plurality of conductive posts 300 may include a metal, such as Cu, aluminum (Al), tungsten (W), Ti, Ta, indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof but is not limited thereto.

The semiconductor package 10 may include external connection terminals CT1 on the lower surface of the lower redistribution structure RDLa. The external connection terminals CT1 may be uniformly disposed on at least a partial region of the lower surface of the lower redistribution structure RDLa. Accordingly, the external connection terminals CT1 may uniformly receive stress from the outside such that cracks occurring in some of the external connection terminals CT1 are suppressed.

The external connection terminals CT1 may be formed on the lower surface of the lower redistribution structure RDLa. The external connection terminals CT1 may include, for example, a solder ball, a conductive paste, a ball grid array (BGA), a lead grid array (LGA), a pin grid array (PGA), or a combination thereof.

In some embodiments, the plurality of lower vertical vias RVa inside the lower redistribution structure RDLa may be structurally formed to have a tapered shape having a width in the first direction X and/or a width in the second direction Y, which gradually increases toward the lower surface of the semiconductor chip 100. That is, the plurality of lower vertical vias RVa inside the lower redistribution structure RDLa may have a horizontal area gradually increasing toward the semiconductor chip 100.

As shown in FIG. 6, the lower redistribution structure RDLa may have three lower wiring layers RLa and three lower vertical vias RVa.

The semiconductor chip 100 may generate heat during an operation process, and the heat generated from the semiconductor chip 100 may be transferred to the molding layer ML. The semiconductor encapsulation composition according to some embodiments of the inventive concept, which is included in the molding layer ML, may be characterized in that the thermal conductivity is at least 5 W/mK, and the composition ratio of the semiconductor encapsulation composition may be the same as described with reference to FIGS. 1 to 5.

The inorganic filler included in the semiconductor encapsulation composition may include one or two among SiO₂, Al₂O₃, AlN, BN, MgO, and a compound thereof. When the composition ratio of the diamond powder according to the inventive concept in a filler is 100 wt. %, the thermal conductivity of the filler may be about 4 W/mK to about 6 W/mK, and the heat diffusion rate of the filler may be about 3 mm²/sec to about 4 mm²/sec.

While the inventive concept has been particularly shown and described with reference to embodiments thereof, it will be understood that various changes in form and details may be made therein without departing from the spirit and scope of the following claims.

What is claimed is:

1. A semiconductor encapsulation composition comprising:
a polymer resin including a mesogen unit;
a hardener; and
a filler including diamond powder,
wherein the mesogen unit includes a compound configured to increase a thermal conductivity of the polymer resin.

2. The semiconductor encapsulation composition of claim 1, wherein a composition ratio of the filler is 60 wt. % to 95 wt. % with reference to a total weight of the semiconductor encapsulation composition.

3. The semiconductor encapsulation composition of claim 2, wherein the filler further comprises one or more inorganic compounds, wherein a composition ratio of the diamond powder is at least 10 wt. % and less than 100 wt. % with reference to a weight of the filler, and a composition ratio of the one or more inorganic compounds is 90 wt. % or less with reference to the weight of the filler.

4. The semiconductor encapsulation composition of claim 1, wherein a thermal conductivity of the diamond powder is 1000 W/mK to 2200 W/mK.

5. The semiconductor encapsulation composition of claim 1, wherein a size of each grain of the diamond powder is 20 micrometers to 30 micrometers.

6. The semiconductor encapsulation composition of claim 1, wherein a composition ratio of the polymer resin is 3 wt. % to 20 wt. % with reference to a total weight of the semiconductor encapsulation composition.

7. The semiconductor encapsulation composition of claim 6, wherein the polymer resin including the mesogen unit is a high heat-dissipating resin and a composition ratio of the high heat-dissipating resin is 10 wt. % to 100 wt. % with reference to a weight of the polymer resin.

8. The semiconductor encapsulation composition of claim 1, wherein the polymer resin including the mesogen unit comprises at least one of Chemical formulae 1 and 2 below

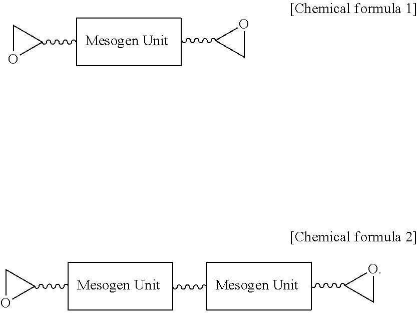

9. The semiconductor encapsulation composition of claim 8, wherein the mesogen unit comprises one of Chemical formulae 3a to 3h below, wherein R in the chemical formula 3h is one of hydrogen (H), chlorine (Cl), and a methyl group (CH₃).

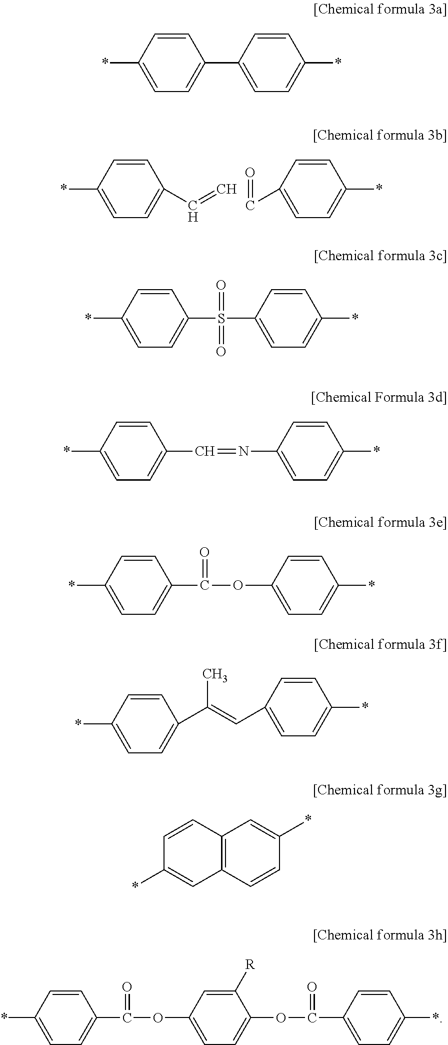

10. The semiconductor encapsulation composition of claim 1, further comprising one or more additives configured to adjust a reaction rate between the polymer resin and the hardener.

11. The semiconductor encapsulation composition of claim 10, wherein a composition ratio of the hardener is 2 wt. % to 10 wt. % with reference to a total weight of the semiconductor encapsulation composition, and a composition ratio of the one or more additives is 10 wt. % or less with reference to the total weight of the semiconductor encapsulation composition.

12. A semiconductor encapsulation composition comprising:
a polymer resin comprising first and second resins made of different materials, the second resin including a high heat-dissipating resin;
a hardener configured to form a matrix by reacting with the polymer resin;
a filler comprising only diamond powder or including a mixture of diamond powder and an additional inorganic filler; and
an additive configured to adjust a reaction rate between the polymer resin and the hardener,
wherein a composition ratio of the filler is 60 wt. % to 95 wt. % with reference to a total weight of the semiconductor encapsulation composition, a composition ratio of the polymer resin is 3 wt. % to 20 wt. % with reference to the total weight of the semiconductor encapsulation composition, and a thermal conductivity of the semiconductor encapsulation composition is at least 5 W/mK.

13. The semiconductor encapsulation composition of claim 12, wherein a composition ratio of the inorganic filler is 0 wt. % to 90 wt. % with reference to a weight of the filler, and the inorganic filler comprises one or two among silicon dioxide (SiO₂), aluminum oxide (Al₂O₃), aluminum nitride (AlN), boron nitride (BN), magnesium oxide (MgO), and a compound thereof.

14. The semiconductor encapsulation composition of claim 12, wherein a composition ratio of the diamond powder is 10 wt. % to 100 wt. % with reference to a weight of the filler, a size of grains of the diamond powder is 20 micrometers to 30 micrometers, and a thermal conductivity of the diamond powder is 1000 W/mK to 2200 W/mk.

15. The semiconductor encapsulation composition of claim 14, wherein, when the composition ratio of the diamond powder is 100 wt. % with reference to the weight of the filler, the thermal conductivity of the semiconductor encapsulation composition is about 4 W/mK to about 6 W/mK, and a heat diffusion rate is about 3 mm²/sec to about 4 mm²/sec.

16. The semiconductor encapsulation composition of claim 12, wherein a composition ratio of the high heat-dissipating resin is at least 10 wt. % with reference to a weight of the polymer resin, the high heat-dissipating resin comprises a polymer having at least one mesogen unit, and a thermal conductivity of the high heat-dissipating resin is at least 0.3 W/mK.

17. The semiconductor encapsulation composition of claim 12, wherein a composition ratio of the hardener is 2 wt. % to 10 wt. % with reference to the total weight of the semiconductor encapsulation composition, a composition ratio of the additive is 10 wt. % or less with reference to the total weight of the semiconductor encapsulation composition, and the hardener comprises a thermosetting agent having an anhydride group.

18. A semiconductor package comprising:
a lower redistribution structure;
a semiconductor chip on an upper surface of the lower redistribution structure;
a plurality of conductive posts on the upper surface of the lower redistribution structure and spaced apart from the semiconductor chip in a direction parallel to the upper surface of the lower redistribution structure; and
a molding layer covering the upper surface of the lower redistribution structure and surrounding the semiconductor chip and the plurality of conductive posts, and comprising a semiconductor encapsulation composition, wherein the semiconductor encapsulation composition comprises:
a polymer resin comprising first and second resins made of different materials, the second resin including a high heat-dissipating resin;
a hardener;
a filler comprising diamond powder or including a mixture of the diamond powder and an additional inorganic filler; and
an additive configured to adjust a reaction rate between the polymer resin and the hardener, wherein a thermal conductivity of the semiconductor encapsulation composition is at least 5 W/mK.

19. The semiconductor package of claim 18, wherein a composition ratio of the polymer resin is 3 wt. % to 20 wt. % with reference to a total weight of the semiconductor encapsulation composition, a composition ratio of the hardener is 2 wt. % to 10 wt. % with reference to the total weight of the semiconductor encapsulation composition, a composition ratio of the filler is 60 wt. % to 95 wt. % with reference to the total weight of the semiconductor encapsulation composition, and a composition ratio of the additive is 10 wt. % or less with reference to the total weight of the semiconductor encapsulation composition.

20. The semiconductor package of claim 18, wherein a composition ratio of the diamond powder is 10 wt. % to 100 wt. % with reference to a weight of the filler, a composition ratio of the high heat-dissipating resin is 10 wt. % to 100 wt. % with reference to a weight of the polymer resin, and the high heat-dissipating resin is a polymer having at least one mesogen unit.
